(19) United States
(12) Patent Application Publication
(10) Pub. No.: US 2013/0221498 A1
(43) Pub. Date: Aug. 29, 2013

(54) SEMICONDUCTOR DEVICE AND METHOD FOR MANUFACTURING THE SAME

(71) Applicant: Hirokazu HAYASHI, Hyogo-ken (JP)

(72) Inventor: Hirokazu HAYASHI, Hyogo-ken (JP)

(73) Assignee: Kabushiki Kaisha Toshiba, Tokyo (JP)

(21) Appl. No.: 13/601,952

(22) Filed: Aug. 31, 2012

(30) Foreign Application Priority Data
Feb. 29, 2012 (JP) P2012-044157

(51) Int. Cl. H01L 29/02; H01L 21/20

(52) U.S. Cl. 257/655; 438/478; 438/530; 257/E21.09; 257/E29.002

(57) ABSTRACT

A semiconductor device having a trench gate structure is formed by self alignment. The manufacturing method of the semiconductor device includes: forming a control electrode in an interior of trenches, etching a semiconductor layer between adjacent trenches to form an opening having a depth that is about level with an upper end of the control electrode with a portion of the semiconductor layer remaining between the opening and the control electrode, forming a first semiconductor region of the second conductive type from the surface of the semiconductor layer to a depth above the lower end of the control electrode, forming a single crystallized conductive layer from the first semiconductor region and the portion of the semiconductor layer, and forming a second semiconductor region, the second semiconductor region including the portion of the semiconductor layer and the single crystallized portion of the conductive layer.

### CROSS-REFERENCE TO RELATED APPLICATION

This application is based upon and claims the benefit of priority from Japanese Patent Application No. 2012-044157, filed Feb. 29, 2012; the entire contents of which are incorporated herein by reference.

### FIELD

Embodiments described herein relate to a semiconductor device and its manufacturing method.

### BACKGROUND

In order to decrease the ON resistance of a power semiconductor device, the chip structure for the power semiconductor device has become increasingly fine. For example, in a MOSFET (metal oxide semiconductor field effect transistor) having a trench gate structure, a decrease in the ON resistance of the MOSFET may be achieved by decreasing the gate interval to make it possible for an increase in the channel width.

However, as the chip structure is made finer, a corresponding upgrade in photolithography process is needed, leading to a rise in the manufacturing cost. As a result, a manufacturing method using the so-called self alignment technology, independent of photolithography, is desirable.

### DESCRIPTION OF THE DRAWINGS

FIG. 1 is a schematic cross-sectional view illustrating a semiconductor device according to a first embodiment.

FIGS. 2A to 2C are schematic cross-sectional views of the semiconductor device according to the first embodiment at various steps of manufacturing.

FIGS. 3A and 3B are schematic cross-sectional views of the semiconductor device according to the first embodiment at various steps of manufacturing after those shown in FIGS. 2A to 2C.

FIGS. 4A and 4B are schematic cross-sectional views of the semiconductor device according to the first embodiment at various steps of manufacturing after those shown in FIGS. 3A and 3B.

FIGS. 5A and 5B are schematic cross-sectional views of the semiconductor device according to the first embodiment at various steps of manufacturing after those shown in FIGS. 4A and 4B.

FIGS. 6A and 6B are schematic cross-sectional views of the semiconductor device according to the first embodiment at various steps of manufacturing after those shown in FIGS. 5A and 5B.

FIGS. 7A and 7B are schematic cross-sectional views of the semiconductor device according to the first embodiment at various steps of manufacturing after those shown in FIGS. 6A and 6B.

FIGS. 8A and 8B are schematic cross-sectional views of the semiconductor device according to the first embodiment at various steps of manufacturing after those shown in FIGS. 7A and 7B.

FIGS. 9A and 9B are schematic cross-sectional views of the semiconductor device according to the first embodiment at various steps of manufacturing after those shown in FIGS. 8A and 8B.

FIGS. 10A to 10C are schematic cross-sectional views of the semiconductor device according to a modified example of the first embodiment at various steps of manufacturing.

FIG. 11 is a schematic cross-sectional view illustrating a semiconductor device according to a second embodiment.

FIGS. 12A and 12B are schematic cross-sectional views of the semiconductor device according to the second embodiment at various steps of manufacturing.

FIGS. 13A and 13B are schematic cross-sectional views of the semiconductor device according to the second embodiment at various steps of manufacturing after those shown in FIGS. 12A and 12B.

### DETAILED DESCRIPTION

In general, each embodiment of the present disclosure will be explained with reference to figures. As used herein, the same reference numbers will be used throughout the figures to refer to previously presented components, and repeated components will not be described repeatedly. Only newly presented components will be explained. In the embodiment described below, the first conductive type or the first electroconductive type refers to the n-type and the second conductive type or the second electroconductive type refers to the p-type or vise versa. Also, explanations will be made using appropriate reference to the X-Y orthogonal coordinates described in the figures.

Embodiments disclosed herein provide a semiconductor device, which has a trench gate structure formed using the self alignment technology, and a method for manufacturing method the same.

The manufacturing method of the semiconductor device includes the steps of forming a control electrode in an interior of trenches, etching a semiconductor layer between adjacent trenches to form an opening having a depth that is about level with an upper end of the control electrode with a portion of the semiconductor layer remaining between the opening and the control electrode, forming a first semiconductor region of the second conductive type from the surface of the semiconductor layer to a depth above the lower end of the control electrode, forming a single crystallized conductive layer from the first semiconductor region and the portion of the semiconductor layer, forming a second semiconductor region, the second semiconductor region including the portion of the semiconductor layer impurities of the first conductive type contained in the conductive layer have diffused and the single crystallized portion of the conductive layer, and forming a main electrode that electrically connects the second semiconductor region and the third semiconductor region.

### Embodiment 1

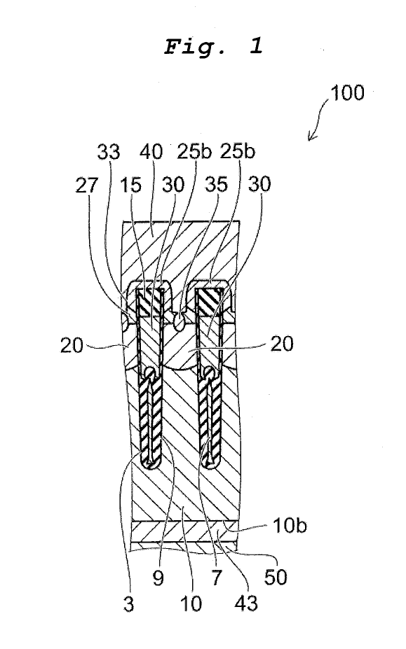

FIG. 1 is a schematic cross-sectional view illustrating a semiconductor device 100 according to this embodiment. The semiconductor device 100 may be, for example, a power MOSFET having a trench gate structure, and may be made using a silicon wafer. For example, it may use a wafer prepared by epitaxial growth of a low-concentration n-type silicon layer on an n-type silicon wafer.

In the following explanation, example steps involved in manufacturing using a silicon wafer will be presented. However, embodiment are not limited to the aforementioned type of wafer. For example, one may also use silicon carbide (SiC), gallium nitride (GaN), or other compound semiconductors.

As depicted, the semiconductor device 100 has an n-type drift layer 10 (n-type semiconductor layer) as an n-type silicon layer, a p-type base region 20 (first semiconductor region), and an n-type source region 27 (second semiconductor region). Here, the p-type base region 20 is formed on the n-type drift layer 10, and the n-type source region 27 is formed on the p-type base region 20. A gate electrode 30 (first control electrode) is arranged inside each trench 3. Each trench 3 is formed in the n-type source region 27 and the p-type base region 20, and extends downwards to a depth within the n-type drift layer 10. A gate insulating film 5 is disposed between the gate electrode 30 and the n-type source region 10 and is also disposed between the gate electrode 30 and the p-type base region 20 and the n-type source region 27. Each trench 3 is formed in a stripe shape extending downwards in the depth direction (hereinafter referred to as the “Y-direction”) shown in FIG. 1.

The semiconductor device 100 has a contact hole 33 arranged at the center of the n-type source region 27; it also has a p-type contact region 35 (third semiconductor region) arranged on the bottom surface of the contact hole. Also, a source electrode 40 covers the trench 3 and the n-type source region 27 from above and extends downwards to the interior of the contact hole 33. At the contact hole 33, the source electrode 40 is in contact with the n-type source region 27 and the p-type contact region 35. The p-type contact region 35 is in contact with the p-type base region 20 at the bottom surface of the contact hole 33, thereby forming a p-type region that connects the p-type base region 20 and the source electrode 40.

On the gate electrode 30, an insulating film 15 (second insulating film) is arranged to provide insulation between the source electrode 40 and the gate electrode 30.

In addition, according to the present embodiment, an n-type polysilicon layer 25b covers the insulating film 15. Here, the n-type polysilicon layer 25b completely covers the top surface of the insulating film 15, and is connected with the n-type source region 27. Also, the source electrode 40 is located above the n-type polysilicon layer 25b, which in turn covers the gate insulating film 5 and the insulating film 15.

On the other hand, on the lower surface side of the n-type drift layer 10, a drain electrode 50 is arranged. Here, the drain electrode 50 is electrically connected with the n-type drift layer 10 via the n-type drain layer 43 which is in contact with the lower surface 10b of the n-type drift layer 10.

Also, a field plate electrode 7 (second control electrode) is arranged between the bottom portion of the trench 3 and the gate electrode 30. Also, a field plate insulating film 9 is disposed between the field plate electrode 7 and the n-type drift layer 10.

The field plate electrode 7 is electrically connected with the source electrode 40 (at a location not shown in the figure) to control the electric field distribution of the n-type drift layer 10. In this way, it is possible to increase the voltage rating between the drain and the source.

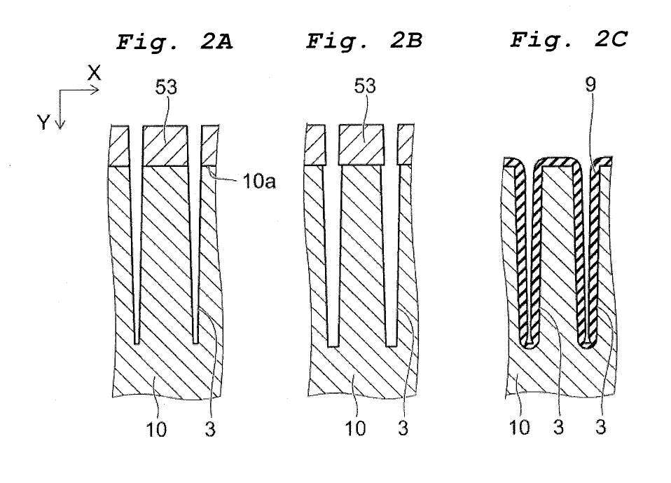

In the following paragraphs, the manufacturing method of the semiconductor device 100 will be explained with reference to FIGS. 2A through 9B. FIGS. 2A through 9B are schematic cross-sectional views of the semiconductor device 100 at various steps of the manufacturing process.

As shown in FIG. 2A, trenches 3 are formed on the n-type semiconductor layer 10. At this point, for example, the n-type semiconductor layer 10 is an n-type silicon layer with a thickness in the range of 5 to 10 μm and an impurity concentration in the range of 1×10¹⁶ to 3×10¹⁶ cm⁻³.

On the upper surface 10a of the n-type semiconductor layer 10, for example, an etching mask 53 made of a silicon oxide film is formed and, using the RIE (reactive ion etching) method, a plurality of trenches 3 are formed. Here, the trenches 3 are formed side-by side on the upper surface 10a of the n-type semiconductor layer 10. For example, as depicted in FIG. 2A, they are formed in a stripe shape extending in the depth direction. The pitch of the side-by side trenches 3 may be, e.g., 1 μm or smaller.

Then, as shown in FIG. 2B, on the inner surface of each trench 3, etching may be conducted using, as an example, the CDE (chemical dry etching) method. The etching increases the width of the trench. As a result, the damage layer formed on the inner surface of the trench 3 during the RIE process is removed. Consequently, the width of each trench 3 may be increased to 0.3 to 0.5 μm, for example, and the depth D_{T} may be between 1 to 10 μm.

Subsequently, the etching mask 53 is removed and, as shown in FIG. 2C, the field plate insulating film 9 covering the inner surface of each trench 3 is formed. Here, the field plate insulating film 9 may be, for example, a silicon oxide film (SiO₂ film) formed by thermal oxidation of the n-type semiconductor layer 10 (n-type silicon layer). The film may have a thickness in the range of 50 to 200 nm.

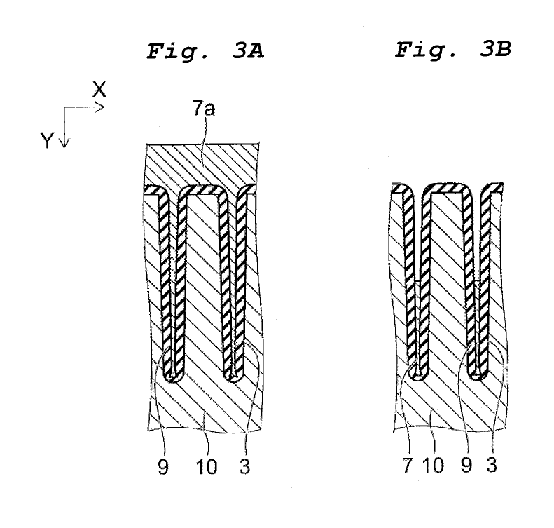

Then, as shown in FIG. 3A, a polysilicon layer (polycrystal silicon layer) 7a which fills the interior of each trench 3 is formed. Here, the polysilicon layer 7a is formed using the CVD (chemical vapor deposition) method. In addition, n-type impurities are diffused in the polysilicon layer 7a to impart electroconductivity.

As shown in FIG. 3B, the polysilicon layer 7a is then etched back to form a field plate electrode 7 in the lower portion of each trench 3. For example, the CDE method may be adopted in the etching of the polysilicon layer 7a.

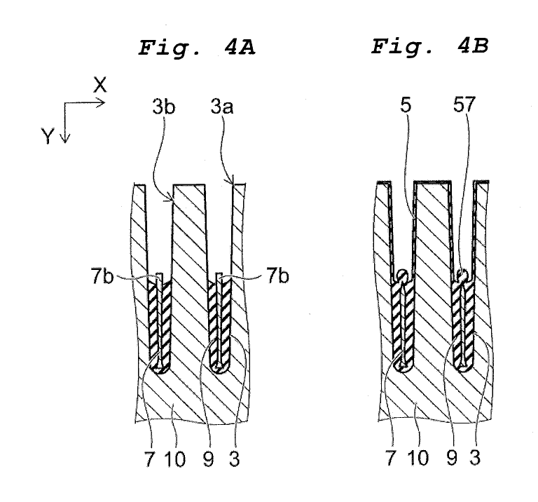

Then, as shown in FIG. 4A, the field plate insulating film 9 between the opening 3a of the trench 3 and the field plate electrode 7 is removed by, e.g., the wet etching method, thereby leaving the upper end 7b of the field plate electrode 7 exposed.

Then, as shown in FIG. 4B, the gate insulating film 5 (first insulating film) is formed on the wall surface 3b of each trench 3. For example, the gate insulating film 5 may be a silicon oxide film formed by thermally oxidizing the n-type semiconductor layer 10 exposed at the wall surface 3b. Here, the gate insulating film 5 is formed so as to be thinner than the field plate insulating film 9. At the same time, the upper end 7b of the field plate electrode 7 is thermally oxidized to form an insulating layer 57.

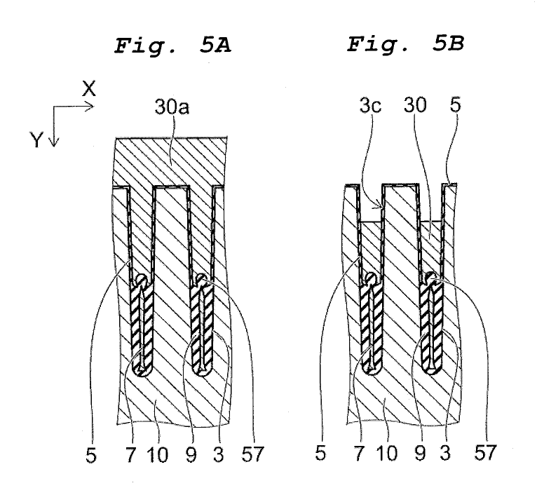

Then, as shown in FIG. 5A, the polysilicon layer (polycrystal silicon layer) 30a that buries the upper portion of the trench 3 is formed. The polysilicon layer 30a may be formed, for example, by using the CVD method. In addition, n-type impurities are diffused in the polysilicon layer 30a to provide electroconductivity.

Then, as shown in FIG. 5B, the polysilicon layer 30a is etched back, leaving gate electrode 30 in a position above field plate electrode 7. The polysilicon layer 30a is etched back to a predetermined depth in the trench 3. As a result, a space 3c is formed in the trench above the gate electrode 30. Also, the field plate insulating film 9 is disposed between the gate electrode 30 faces the n-type semiconductor layer 10. The field plate electrode 7 and the gate electrode 30 are insulated from each other by the insulating layer 57.

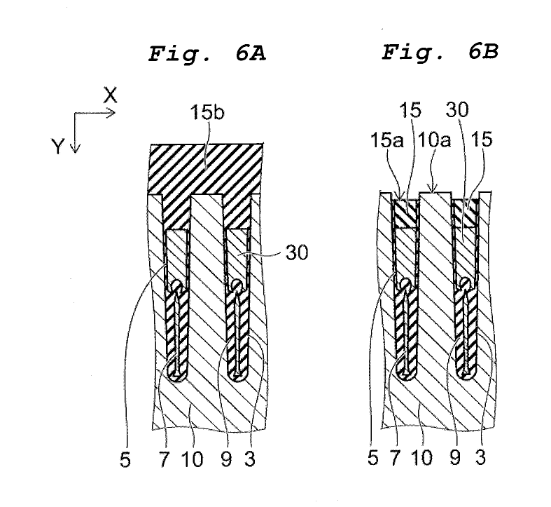

Then, as shown in FIG. 6A, an insulating film 15b is formed (second insulating film) which buries the space 3c above gate electrode 30. The insulating film 15b may be, for example, a silicon oxide film, and may be formed using TEOS (tetraethoxysilane) by the CVD method.

Then, as shown in FIG. 6B, the insulating film 15b is etched back using a technique such as the RIE method. The amount of etching is controlled so that the upper surface 15a of the insulating film 15 is at a depth nearly equivalent to the depth of the upper surface 10a of the n-type semiconductor layer 10.

In addition, by wet etching the upper surface 15a of the insulating film 15, this upper surface becomes concave (i.e., lower than the upper surface 10a of the n-type semiconductor layer 10). For example, etching may be carried out by using an etching solution containing dilute hydrofluoric acid. As depicted, the upper end of the gate insulating film 5 is disposed along the wall surface of the trench 3 and occupies space between the insulating film 15 and the n-type semiconductor layer 10.

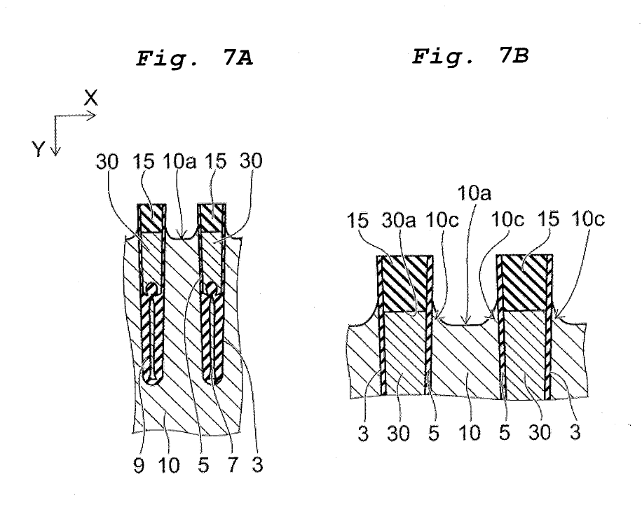

Then, as shown in FIG. 7A, the n-type semiconductor layer 10 is etched between the trenches 3 so as to create an upper surface 10a positioned slightly below the upper end 30a of the gate electrode 30. The etching depicted in FIG. 7A may be carried out, for example, using the RIE method and a 1:7 selection ratio of the silicon oxide film to silicon.

FIG. 7B is a partial cross-sectional view illustrating the result of the semiconductor fabrication process after etching the n-type semiconductor layer 10 between the a trenches 3. The upper surface 10a of the n-type semiconductor layer 10 is located lower than the upper end 30a of the gate electrode 30. Furthermore, the residual portions remaining to the right and left of the upper surface 10a of the n-type semiconductor layer 10 extend upwards along the gate insulating film 5.

In this embodiment, the n-type semiconductor layer 10 is etched so that the portion facing the gate electrode 30 via the gate insulating film 5 is left. For example, under the RIE condition with anisotropy to ensure that the trench 3 has a tapered shape, with the width in the lateral direction (X-direction) arranged narrower than the depth direction (Y-direction), the n-type semiconductor layer 10 can be etched so that the portion extending along the gate insulating film 5 (to be referred to as residual portion 10c) is left.

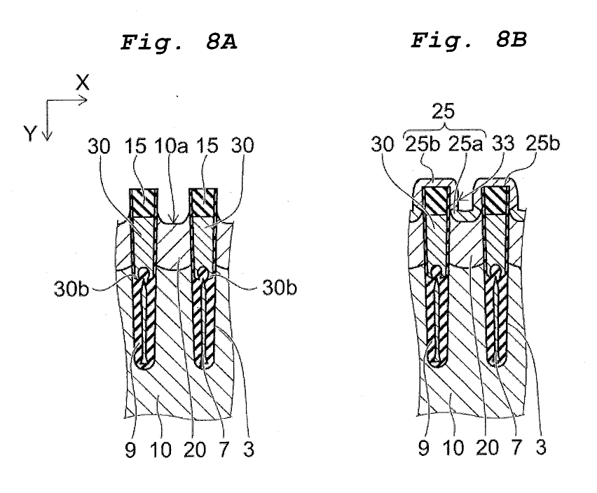

Then, as shown in FIG. 8A, a p-type base region 20 is formed from the upper surface 10a of the n-type semiconductor layer 10 in the depth direction (Y-direction). The p-type base region 20 may be formed, for example, by implanting boron (B) as p-type impurity into the upper surface 10a of the n-type semiconductor layer 10, followed by heat treatment to activate the boron while it diffuses in the Y-direction. The concentration of the p-type impurity of the p-type base region 20 may be, for example, in the range of 5×10¹⁶ to 5×10¹⁷ cm⁻³.

The p-type base region 20 is arranged to begin at the upper surface 10a of the n-type semiconductor layer 10 to a depth between the upper end 30a and lower end 30b of the gate electrode 30. Thus, the lower end of p-type base region 20 is no deeper than the lower end 30b of the gate electrode 30.

Then, as shown in FIG. 8B, the n-type electroconductive layer 25 is formed on the upper surfaces of the gate insulating film 5, the insulating film 15, the residual portion 10c of the n-type semiconductor layer 10 and the p-type base region 20. The n-type electroconductive layer 25 includes the n-type silicon region 25a formed on the surfaces of the residual portion 10c and the p-type base region 20, and the n-type polysilicon layer 25b formed on the surfaces of the gate insulating film 5 and the insulating film 15. In one embodiment, the CVD method is used to promote epitaxial growth of the single crystallized n-type silicon region 25a that is in contact with the surface of the p-type base region 20 and the surface of the residual portion 10c. In such an embodiment, the n-type polysilicon layer 25b is formed on the surface of the gate insulating film 5 and the insulating film 15. For example, phosphorus (P) as an n-type impurity is doped in the n-type silicon region 25a and the n-type polysilicon layer 25b, and the impurity concentration is in the range of 5×10¹⁸ to 2×10¹⁹ cm⁻³.

In addition, on the two side residual portions 10c, the n-type silicon region 25a is grown in the lateral direction (X-direction). For this purpose, the contact hole 33 is formed at the center of the n-type silicon region 25a. The width of the contact hole 33 can be controlled by adjusting the interval between the trenches 3 in the X-direction and the thickness of the n-type silicon region 25a.

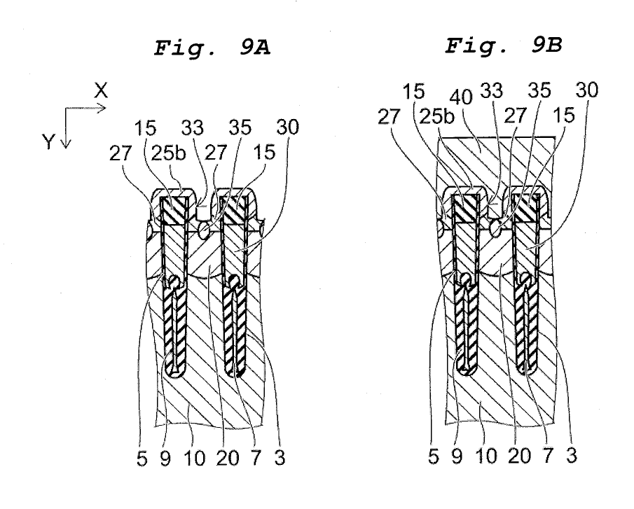

Then, as shown in FIG. 9A, on the bottom surface of the contact hole 33, a p-type impurity, e.g., boron (B), is ion implanted to form a p-type contact region 35. The concentration of the p-type impurity in the p-type contact region 35 is, e.g., in the range of 1×10¹⁸ to 5×10¹⁸ cm⁻³. This impurity concentration and it is higher than the concentration of the p-type impurity in the p-type base region 20. Also, the p-type contact region 35 is formed as a p-type region in contact with the p-type base region 20.

Also, in the heat treatment for activating the p-type impurity that is ion implanted in the bottom surface of the contact hole 33, the n-type impurity contained in the n-type silicon region 25a diffuses to the residual portion 10c. This diffusion serves to convert the electroconductive type of residual portion 10c to the n-type.

In the aforementioned step, for example, the p-type impurity can be ion implanted to the entire surface of the wafer without forming an implanting mask. That is, by implanting the p-type impurity perpendicular to the wafer surface, the quantity of the p-type impurity implanted into the wall surface of the contact hole 33 can be less than the quantity of the p-type impurity implanted into the bottom surface of the contact hole 33. Consequently, on the bottom surface of the contact hole, it is possible to have the n-type silicon region 25a converted to the p-type to form a p-type contact region 35, while the n-type silicon region 25a exposed on the wall surface of the contact hole 33 is maintained as n-type. As a result, the p-type contact region 35 is selectively formed and it is possible to form the n-type source region 27 including the residual portion 10c and the n-type silicon region 25a.

As shown in FIG. 9A, the n-type source region 27 is formed on the p-type base region 20, and gate insulating film 5 is disposed between the n-type source region 27 and the gate electrode 30. In addition, the n-type source region 27 is in contact with the n-type polysilicon layer 25b.

Then, as shown in FIG. 9B, a source electrode 40 is formed which covers the gate insulating film 5, the insulating film 15, and the n-type polysilicon layer 25b and which extends inside the contact hole 33. The source electrode 40 is in contact with the p-type contact region 35 and the n-type source region 27 inside the contact hole 33.

The source electrode 40 may contain, e.g., aluminum. In addition, for example, the source electrode 40 may have a barrier metal layer containing titanium tungsten (TiW) which may be disposed between the n-type source region 27 and the p-type contact region 35.

As mentioned previously, according to the manufacturing method of the present embodiment, instead of photolithography, the self alignment method is used to form the contact hole 33 between the trenches 3. Then, the source electrode 40 can be formed in a trench contact structure such that it is in contact with the n-type source region 27 and the p-type contact region 35. In addition, the contact hole 33 can be configured with a width of 0.1 μm or smaller, and it is possible to realize fine processing at a low cost.

In addition, the n-type polysilicon layer 25b is formed between the gate insulating film 5 as well as insulating film 15 and the source electrode 40. As a result, it is possible to minimize the stress generated between the gate insulating film 5, the insulating film 15 and the source electrode 40; it is also possible to improve the close contact property between the source electrode 40, the gate insulating film 5 and/or insulating film 15. As a result, it is possible to improve the reliability of the semiconductor device 100.

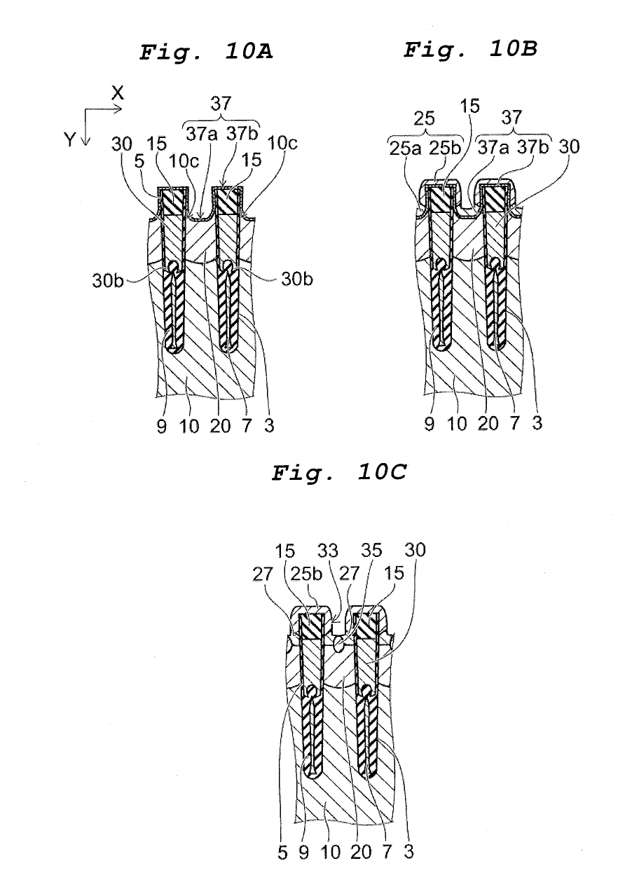

FIGS. 10A to 10C are schematic cross-sectional views of the semiconductor device according to a modified example of Embodiment 1 during manufacturing. As shown in FIG. 10A, in this modified example, a p-type electroconductive layer 37 is formed to cover the surface of the p-type base region 20, the surface of the residual portion 10c of the n-type semiconductor layer 10, the surface of the gate insulating film 5, and insulating film 15. Here, the p-type electroconductive layer 37 includes the p-type silicon region 37a (fourth semiconductor region), formed on the surface of the p-type base region 20 and the surface of the residual portion 10c of the n-type semiconductor layer 10, and the p-type polysilicon layer 37b formed on the surface of the gate insulating film 5 as well as insulating film 15. For example, using the CVD method, the p-type silicon region 37a is formed as an epitaxially grown single crystal silicon on the surface of the p-type base region 20 and the surface of the residual portion 10c. Here, the concentration of the p-type impurity in the p-type silicon region 37a is higher than the concentration of the p-type impurity of the p-type base region 20.

Also, the p-type silicon region 37a may be selectively epitaxially grown on the surface of the p-type base region 20 and the surface of the residual portion 10c.

Then, as shown in FIG. 10B, an n-type electroconductive layer 25 is formed on the p-type electroconductive layer 37. Here, then-type electroconductive layer 25 includes the n-type silicon region 25a formed on the p-type silicon region 37a and the n-type polysilicon layer 25b formed on the p-type polysilicon layer 37b.

Then, as shown in FIG. 10C, on the bottom surface of the contact hole 33, a p-type impurity, e.g., boron (B), is ion implanted to selectively form the p-type contact region 35.

In this modified example, the quantity of the p-type impurity doped in the p-type electroconductive layer 37 is smaller than the quantity of the n-type impurity doped in the n-type electroconductive layer 25. Consequently, the concentration of the p-type impurity in the p-type silicon region 37a is lower than the n-type impurity concentration in the n-type silicon region 25a. Then, due to heat treatment carried out for activating the p-type impurity, the n-type impurity doped in the n-type electroconductive layer 25 diffuses into the p-type electroconductive layer 37 and the residual portion 10c and converts them to the n-type. As a result, it is possible to form the n-type source region 27 to include the n-type silicon region 25a, the p-type silicon region 37a and the residual portion 10c.

On the other hand, the p-type impurity doped in the p-type silicon region 37a diffuses into the n-type silicon region 25a, so that its n-type impurity is compensated, and the concentration of the n-type impurity can be efficiently decreased. As a result, it is possible to facilitate formation of the p-type contact region 35.

That is, when the n-type impurity is doped with a high concentration in the n-type silicon region 25a formed on the p-type base region 20, in order to have the region converted to form a p-type region, it is necessary to increase the dose quantity of the p-type impurity. For example, when the dose quantity of the ion implanted p-type impurity needs to be increased, the implanting time is longer or the ion beam has a higher intensity. However, this leads to a decrease in the manufacturing efficiency and increase in the size of the device and rise in the manufacturing cost. In addition, activation of the impurity implanted at a high dose may be difficult. In this modified example, the p-type silicon region 37a enables decreasing the dose quantity of the p-type impurity on the bottom surface of the contact hole 33. As a result, it is possible to reduce manufacturing costs.

### Embodiment 2

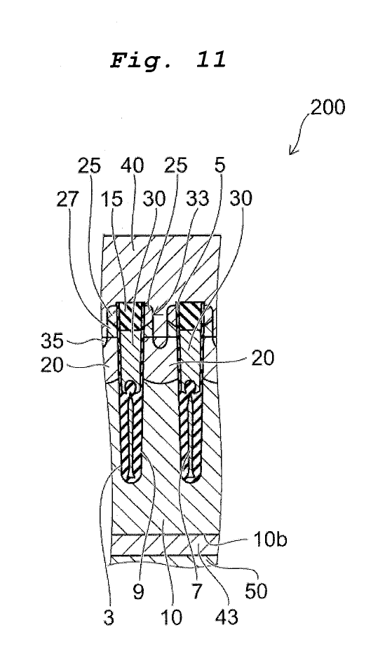

FIG. 11 is a schematic cross-sectional view of the semiconductor device 200 according to a second embodiment. Here, the semiconductor device 200 includes an n-type drift layer 10, a p-type base region 20, and an n-type source region 27. The p-type base region 20 is arranged on the n-type drift layer 10, and the n-type source region 27 is arranged on the p-type base region 20. There is also a gate electrode 30 inside each trench 3.

In this embodiment, the contact hole 33 arranged at the center of the n-type source region 27 is in contact with the p-type base region 20. Then, the p-type contact region 35 is formed on its bottom surface. As a result, the p-type contact region 35 can be formed in the p-type base region 20, and it is possible to decrease the exhausting resistance of the hole from the p-type base region 20 to the source electrode 40.

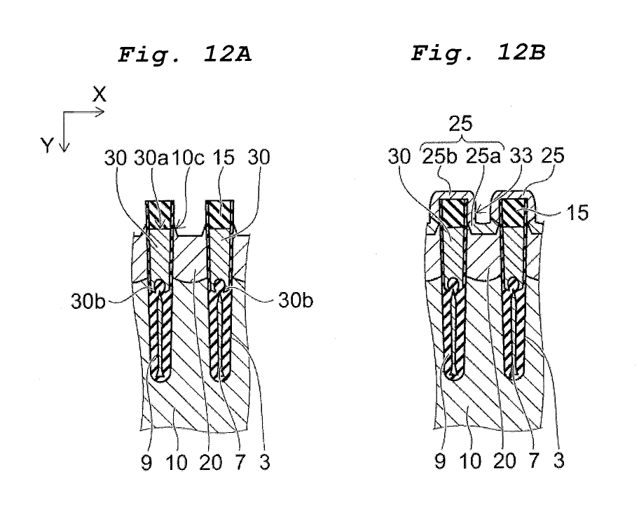

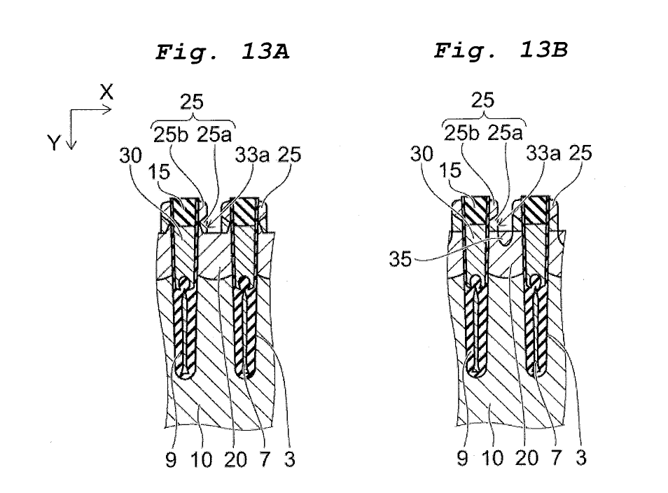

In the following, with reference to FIGS. 12A and 12B and FIGS. 13A and 13B, the manufacturing method of the semiconductor device 200 will be explained. FIGS. 12A and 12B and FIGS. 13A and 13B are schematic cross-sectional views illustrating the manufacturing process of the semiconductor device 200.

As shown in FIG. 12A, the n-type semiconductor layer 10 between the adjacent trenches 3 is etched to a depth slightly below the depth of the upper surface 30a of the gate electrode 30, prior to formation of the p-type base region 20. Once the p-type base region 20 is formed, on the two ends of the p-type base region 20, the residual portion 10c extends upward along the gate insulating film 5.

Then, as shown in FIG. 12B, the n-type electroconductive layer 25 is formed on the surface of the gate insulating film 5, the insulating film 15, the residual portion 10c and the p-type base region 20. The n-type electroconductive layer 25 includes the n-type silicon region 25a formed on the residual portion 10c and on the p-type base region 20; the n-type polysilicon layer 25b formed on the surface of the gate insulating film 5 and on insulating film 15. In addition, a contact hole 33 is formed at the center of the n-type silicon region 25a.

Then, as shown in FIG. 13A, the n-type polysilicon layer 25b formed on the insulating film 15 and the n-type silicon region 25a formed on the bottom surface of the contact hole 33 are etched. For example, etching is carried out under the anisotropic etching condition of RIE, with the etching rate in the Y-direction higher than that in the X-direction as shown in the figure. As a result, for example, the contact hole 33a connected with the p-type base region 20 is formed. Also, as long as the n-type silicon region 25a is etched and formed deep, the contact hole 33a need not be connected with the p-type base region 20.

On the other hand, because the n-type polysilicon layer 25b in contact with the gate insulating film 5 is thick in the Y-direction, it is not entirely etched off, and it is thus left on the n-type silicon region 25a. That is, the n-type silicon region 25a formed on the surface of the residual portion 10c is kept as is without etching.

Then, as shown in FIG. 13B, on the bottom surface of the contact hole 33a, for example, the ion implanting method is adopted to selectively form the p-type contact region 35. Heat treatment is carried out to activate the p-type impurity that is ion implanted in the bottom surface of the contact hole 33a. In this heat treatment, the n-type impurity diffuses from the n-type silicon region 25a into the residual portion 10c, and it changes the region to an n-type region. As a result, the n-type source region including the n-type silicon region 25a and the residual portion 10c is formed.

Then, the source electrode (not shown) is formed to cover the insulating film 15 and the n-type polysilicon layer 25b and extend inside the contact hole 33a. Inside the contact hole 33a, the source electrode 40 is in contact with the surfaces of the n-type source region 27 and the p-type contact region 35, respectively, to provide an electric connection.

In the semiconductor device 200 related to this embodiment, the p-type contact region 35 can be formed deeper below the top of p-type base region 20 than is possible in the fabrication of semiconductor device 100. Consequently, it is possible to decrease the exhausting resistance from the p-type base region 20 and to improve the switching characteristics. Also, it is possible to increase the avalanche voltage rating of the n-type drift layer 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device comprising the steps of:
forming a control electrode in an interior of each of a plurality of trenches arranged side-by-side on a semiconductor layer of a first conductive type, the control electrode separated from the semiconductor layer by a first insulating film;
forming a second insulating film on the control electrode
etching the semiconductor layer between adjacent trenches to form an opening having a center depth below an upper end of the control electrode with a portion of the semiconductor layer remaining between the opening and the control electrode;
forming a first semiconductor region of a second conductive type from the surface of the semiconductor layer to a depth above a lower end of the control electrode;
forming a conductive layer of the first conductive type to cover the surfaces of the first insulating film, the second insulating film and the first semiconductor region;
forming a second semiconductor region of the first conductive type on a side of the first insulating film opposite the control electrode, the second semiconductor region including the portion of the semiconductor layer to which impurities of the first conductive type contained in the conductive layer have diffused;
selectively forming a third semiconductor region of the second conductive type from the surface of the conductive layer to the first semiconductor region; and
forming a main electrode that electrically connects the second semiconductor region and the third semiconductor region.

2. The manufacturing method of semiconductor device according to claim 1, further comprising:
heat treating the semiconductor device to cause the impurities of the first conductive type contained in the conductive layer to diffuse into the portion of the semiconductor layer.

3. The manufacturing method of semiconductor device according to claim 1, wherein the conductive layer includes single crystal silicon grown from the portion of the semiconductor layer and the first semiconductor region.

4. The manufacturing method of semiconductor device according to claim 1, wherein the second semiconductor region includes single crystal silicon grown from the portion of the semiconductor layer and the first semiconductor region.

5. The manufacturing method of semiconductor device according to claim 1, further comprising:
forming a fourth semiconductor region of the second conductive type having an impurity concentration higher than that on the surface of the first semiconductor region.

6. The manufacturing method of semiconductor device according to claim 5, wherein
the impurity of the second conductive type is ion implanted into the surface of the conductive layer, and heat treatment is then carried out so that the second semiconductor region and the third semiconductor region are simultaneously formed.

7. The manufacturing method of semiconductor device according to claim 5, wherein the conductive layer is formed on the fourth semiconductor region.

8. The manufacturing method of semiconductor device according to claim 7, wherein the impurity concentration of the fourth semiconductor region is less than an impurity concentration of the conductive layer.

9. A manufacturing method of a semiconductor device comprising the steps of:
forming a control electrode in an interior of each of a plurality of trenches arranged side-by-side on a semiconductor layer of a first conductive type, the control electrode separated from the semiconductor layer by a first insulating film;
forming a second insulating film on the control electrode;
etching the semiconductor layer between adjacent trenches to form an opening having a center depth below an upper end of the control electrode with a portion of the semiconductor layer remaining between the opening and the control electrode;
forming a first semiconductor region of a second conductive type from the surface of the semiconductor layer to a depth above a lower end of the control electrode;
forming a conductive layer of the first conductive type to cover the surfaces of the first insulating film, the second insulating film and the first semiconductor region;
etching the conductive layer to expose the first semiconductor region;
implanting impurities of the second conductivity type into the exposed region of the first semiconductor region;
forming a second semiconductor region of the first conductive type on a side of the first insulating film opposite the control electrode, the second semiconductor region including the portion of the semiconductor layer to which impurities of the first conductive type contained in the conductive layer have diffused; and
forming a main electrode that electrically connects the second semiconductor region and the third semiconductor region.

10. The manufacturing method of semiconductor device according to claim 9, further comprising:
heat treating the semiconductor device to cause the impurities of the first conductive type contained in the conductive layer to diffuse into the portion of the semiconductor layer.

11. The manufacturing method of semiconductor device according to claim 9, wherein the conductive layer includes single crystal silicon grown from the portion of the semiconductor layer and the first semiconductor region.

12. The manufacturing method of semiconductor device according to claim 9, wherein the second semiconductor region includes single crystal silicon grown from the portion of the semiconductor layer and the first semiconductor region.

13. The manufacturing method of semiconductor device according to claim 9, wherein the conductive layer is etched anisotropcially.

14. The manufacturing method of semiconductor device according to claim 13, wherein the conductive layer is etched by reactive ion etching.

15. A semiconductor device comprising:
a semiconductor layer of a first conductive type;
a first semiconductor region of a second conductive type arranged on the semiconductor layer;
a second semiconductor region of the first conductive type arranged on the first semiconductor region;
a control electrode formed through the second semiconductor region and the first semiconductor region to a depth reaching the semiconductor layer,
a first insulating film disposed between the first control electrode and each of the first semiconductor region and the second semiconductor region;
a third semiconductor region disposed at a bottom part of a contact hole arranged in the second semiconductor region;
a second insulating film formed above the control electrode;
a conductive layer of the first conductive type that covers the second insulating film and is electrically connected to the second semiconductor region; and
a main electrode that extends inside the contact hole and is in contact with the second semiconductor region and the third semiconductor region.

16. The semiconductor device according to claim 15, wherein the control electrode has an upper surface above an upper surface of the first semiconductor region and a lower surface about level with a lower surface of the first semiconductor region.

17. The semiconductor device according to claim 16, wherein the second semiconductor region is disposed on either side of the third semiconductor region.

18. The semiconductor device according to claim 17, wherein an impurity concentration of the third semiconductor region is higher than in impurity concentration of the first semiconductor region.

19. The semiconductor device according to claim 15, further comprising:
a field plate electrode arranged below and in contact with the control electrode.

20. The semiconductor device according to claim 19, further comprising a third insulating film disposed between the field plate electrode and the semiconductor layer.
